(19) United States
(12) Patent Application Publication
(10) Pub. No.: US 2019/0288063 A1
(43) Pub. Date: Sep. 19, 2019

(54) SEMICONDUCTOR DEVICE

(71) Applicants: Kabushiki Kaisha Toshiba, Tokyo (JP); Toshiba Electronic Devices & Storage Corporation, Minato-ku (JP)

(72) Inventors: Kanako Komatsu, Yokohama Kanagawa (JP); Yoshiaki Ishii, Kawasaki Kanagawa (JP)

(21) Appl. No.: 16/125,835

(22) Filed: Sep. 10, 2018

(30) Foreign Application Priority Data
Mar. 19, 2018 (JP) 2018-051534

(51) Int. Cl. H01L 29/06; H01L 29/78; H01L 29/423; H01L 29/66; H01L 21/762

(52) U.S. Cl. CPC H01L 29/0653; H01L 29/7823; H01L 29/0696; H01L 21/31116; H01L 29/66681; H01L 21/76224; H01L 29/4238

(57) ABSTRACT

A semiconductor device includes a semiconductor substrate, a plurality of first insulators provided on in an upper portion of the semiconductor substrate, and a plurality of second insulators provided in the upper portion of on the semiconductor substrate. The second insulators are thicker than the first insulators. The first insulators and the second insulators are arranged alternately.

### CROSS-REFERENCE TO RELATED APPLICATIONS

This application is based upon and claims the benefit of priority from Japanese Patent Application No. 2018-051534, filed on Mar. 19, 2018; the entire contents of which are incorporated herein by reference.

### FIELD

Embodiments relate to a semiconductor device.

### BACKGROUND

In a DMOS (Double-Diffused MOSFET), technology has been proposed in which STI (Shallow Trench Isolation (an element-separating insulator)) is provided between a drain and a channel to ensure the breakdown voltage. On the other hand, the on-resistance increases due to the existence of the STI.

### BRIEF DESCRIPTION OF THE DRAWINGS

FIG. 1 is a plan view showing a semiconductor device according to a first embodiment;

FIG. 2 is a cross-sectional view along line A-A′ shown in FIG. 1;

FIG. 3 is a plan view showing a semiconductor device according to a second embodiment;

FIG. 4 is a cross-sectional view along line B-B′ shown in FIG. 3;

FIG. 5 is a plan view showing a semiconductor device according to a third embodiment;

FIG. 6 is a cross-sectional view along line C-C′ shown in FIG. 5;

FIG. 7 is a cross-sectional view showing a semiconductor device according to a fourth embodiment;

FIG. 8 is a cross-sectional view showing a semiconductor device according to a fifth embodiment;

FIG. 9 is a cross-sectional view showing a semiconductor device according to a sixth embodiment;

FIG. 10 is a cross-sectional view showing a semiconductor device according to a seventh embodiment;

FIG. 11 is a cross-sectional view showing a semiconductor device according to an eighth embodiment;

FIG. 12A is a perspective cross-sectional view showing a semiconductor device according to a ninth embodiment; and

FIG. 12B is a plan view of the semiconductor device according to the ninth embodiment; and

FIGS. 13A to 13C and FIGS. 14A and 14B are cross-sectional views showing a method for manufacturing a semiconductor device according to a tenth embodiment.

### DETAILED DESCRIPTION

A semiconductor device according to one embodiment, includes a semiconductor substrate, a plurality of first insulators provided on in an upper portion of the semiconductor substrate, and a plurality of second insulators provided in the upper portion of on the semiconductor substrate. The plurality of second insulators are thicker than the plurality of first insulators. The first insulators and the second insulators are arranged alternately.

### First Embodiment

First, a first embodiment will be described.

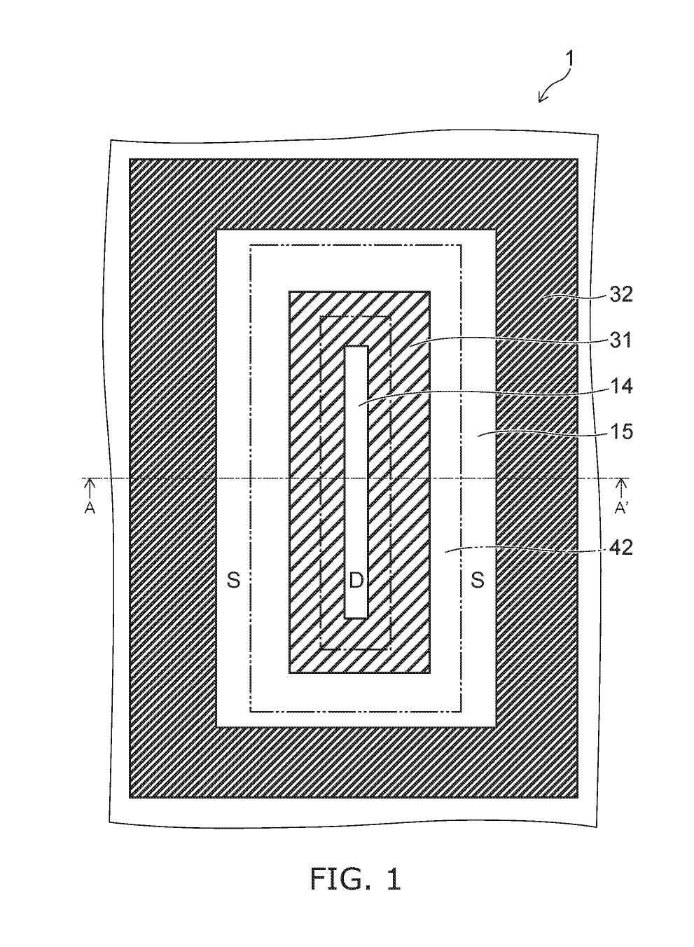

FIG. 1 is a plan view showing a semiconductor device according to the embodiment.

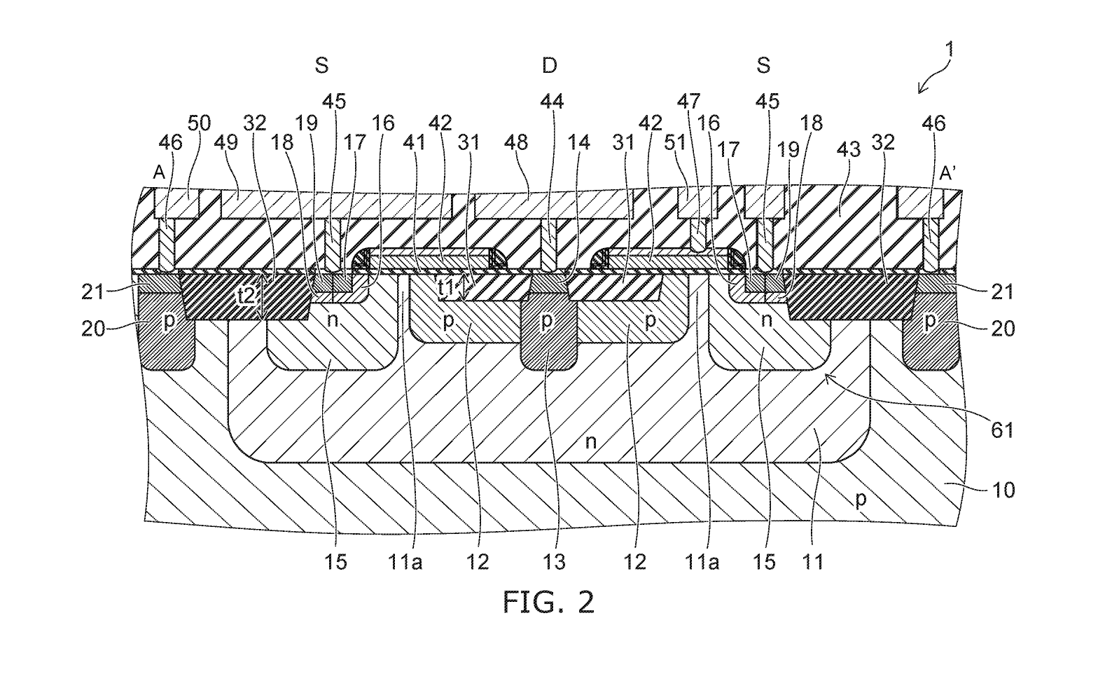

FIG. 2 is a cross-sectional view along line A-A′ shown in FIG. 1.

The drawings are schematic and are drawn with appropriate exaggerations or omissions. For example, the components are drawn to be larger and fewer than the actual components.

As shown in FIG. 1 and FIG. 2, a silicon substrate 10 is provided as a semiconductor substrate in the semiconductor device 1 according to the embodiment. For example, the silicon substrate 10 is made from single-crystal silicon (Si); and the conductivity type of the silicon substrate 10 is a p-type. A deep n-well 11 of an n-type is provided in a portion on the silicon substrate 10.

A drift layer 12 of the p-type and a p-well 13 of the p-type are provided in the central portion on the deep n-well 11. The impurity concentration of the p-well 13 is higher than the impurity concentration of the drift layer 12. The “impurity concentration” is the concentration of the impurity that forms carriers inside silicon. The configurations of the drift layer 12 and the p-well 13 are rectangular configurations when viewed from above, i.e., a direction perpendicular to the upper surface of the silicon substrate 10. The p-well 13 pierces the central portion of the drift layer 12; and the lower surface of the p-well 13 is positioned lower than the lower surface of the drift layer 12. A drain contact layer 14 of the p-type is provided on the p-well 13. The impurity concentration of the drain contact layer 14 is higher than the impurity concentration of the p-well 13.

An n-well 15 of the n-type is provided in the peripheral portion on the deep n-well 11. The configuration of the n-well 15 when viewed from above is a rectangular frame-like configuration surrounding the drift layer 12 and the p-well 13. The n-well 15 is separated from the drift layer 12 and is separated also from the outer surface of the deep n-well 11. A portion 11a of the deep n-well 11 is disposed between the drift layer 12 and the n-well 15.

A source layer 16 of the p-type is provided in a portion on the n-well 15. A source contact layer 17 of the p-type is provided in a portion on the source layer 16. The impurity concentration of the source contact layer 17 is higher than the impurity concentration of the source layer 16. A body layer 18 of the n-type is provided in another portion on the n-well 15. The impurity concentration of the body layer 18 is higher than the impurity concentration of the n-well 15. The body layer 18 contacts the source layer 16. A body contact layer 19 of the n-type is provided in a portion on the body layer 18. The impurity concentration of the body contact layer 19 is higher than the impurity concentration of the body layer 18. The body contact layer 19 contacts the source contact layer 17. The configurations of the source layer 16, the source contact layer 17, the body layer 18, and the body contact layer 19 when viewed from above are frame-like configurations surrounded with the n-well 15.

A p-well 20 of the p-type is provided in a region on the silicon substrate 10 separated from the deep n-well 11. A substrate contact layer 21 of the p-type is provided on the p-well 20.

A STI 31 and a STI 32 are provided as element-separating insulators on the silicon substrate 10. The STI 31 and the STI 32 have a double rectangular frame-like configuration; the STI 31 is disposed on the inner side; and the STI 32 is disposed on the outer side. In other words, the STI 32 is disposed at a position sandwiching the STI 31; and the STI 32 surrounds the STI 31. The STI 31 is provided inside the upper layer portion of the drift layer 12 and surrounds the drain contact layer 14 and the upper portion of the p-well 13.

The STI 32 is disposed along the outer edge of the deep n-well 11. The outer edge of the deep n-well 11 contacts the bottom surface of the STI 32. The STI 32 is disposed over the n-well 15, the deep n-well 11, the silicon substrate 10, and the p-well 20. The inner side surface of the STI 32 contacts the body contact layer 19, the body layer 18, and the n-well 15. The bottom surface of the STI 32 contacts the n-well 15, the deep n-well 11, the silicon substrate 10, and the p-well 20. The outer side surface of the STI 32 contacts the p-well 20 and the substrate contact layer 21. Hereinafter, the region that is surrounded with the STI 32 is called an “element region.”

The STI 31 and the STI 32 both are formed of silicon oxide (SiO). The upper surface of the STI 31 and the upper surface of the STI 32 are positioned in substantially the same plane. On the other hand, the lower surface of the STI 32 is positioned lower than the lower surface of the STI 31. In other words, the STI 32 is thicker than the STI 31. t1<t2, wherein the thickness of the STI 31 is t1, and the thickness of the STI 32 is t2. In an example, the thickness t1 is 80 m; and a thickness t2 is 300 μm.

A gate insulating film 41 that is made of, for example, silicon oxide is provided on the silicon substrate 10; and a gate electrode 42 is provided on the gate insulating film 41. The gate electrode 42 is disposed over a region directly above the STI 31, a region directly above the drift layer 12, a region directly above the portion 11a, and a region directly above the n-well 15. When viewed from above, the configuration of the gate electrode 42 is a frame-like configuration including a region directly above the outer edge of the STI 31.

An inter-layer insulating film 43 is provided to cover the gate electrode 42 on the silicon substrate 10. Contacts 44 to 47 are provided inside the inter-layer insulating film 43. The lower end of the contact 44 is connected to the drain contact layer 14. The lower end of the contact 45 is connected to the source contact layer 17 and the body contact layer 19. The lower end of the contact 46 is connected to the substrate contact layer 21. The lower end of the contact 47 is connected to the gate electrode 42.

Interconnects 48 to 51 are provided inside the inter-layer insulating film 43. The interconnect 48 is connected to the upper end of the contact 44. The interconnect 49 is connected to the upper end of the contact 45. The interconnect 50 is connected to the upper end of the contact 46. The interconnect 51 is connected to the upper end of the contact 47.

By such a configuration, a p-channel DMOS 61 is formed inside the element region partitioned by the STI 32 in the semiconductor device 1. Each of the DMOSs 61 includes the STI 31. In the DMOS 61, a channel region is formed of the n-well 15 and the portion 11a of the deep n-well 11. For convenience in FIG. 1 and FIG. 2, the source side of the DMOS 61 is marked with the reference numeral “S;” and the drain side of the DMOS 61 is marked with the reference numeral “D”. This is similar for the other drawings described below as well.

An operation of the semiconductor device 1 according to the embodiment will now be described.

In the DMOS 61, because the STI 31 is provided between the drain contact layer 14 and the channel region, the on-current flows from the drain contact layer 14 into the source contact layer 17 by detouring below the STI 31. Therefore, in the DMOS 61, the distance between the drain-gate is long; and the breakdown voltage is high.

On the other hand, the DMOS 61 is partitioned from the periphery by the STI 32. Thereby, the breakdown voltage at the element terminal of the DMOS 61 increases.

If the STI 32 is set to be about as thin as the STI 31, it is necessary to set the distance between the n-well 15 and the p-well 20 to be long to ensure the breakdown voltage at the element terminal of the DMOS 61. Thereby, downsizing of the semiconductor device 1 is obstructed. On the other hand, if the STI 31 is set to be about as thick as the STI 32, the breakdown voltage of the DMOS 61 increases; but the resistance of the on-current (hereinbelow, called the “on-resistance”) undesirably becomes high. Also, impact ions are generated at the corners of the STI 32; and holes accumulate easily.

In the embodiment, the STI 32 is set to be thicker than the STI 31. Thereby, the thicknesses of the STI 31 and the STI 32 each can be set optimally. In other words, by setting the STI 32 to be sufficiently thick, even in the case where the distance between the deep n-well 11 and the p-well 20 is set to be short, the DMOS 61 can be separated from the periphery; and downsizing of the semiconductor device 1 can be realized. Also, by selecting the thickness of the STI 31 appropriately, the DMOS 61 can conform to specifications requiring a balance between the on-resistance and the breakdown voltage of the DMOS 61. Thus, according to the embodiment, the DMOS 61 having excellent balance between the on-resistance and the breakdown voltage can be realized.

### Second Embodiment

A second embodiment will now be described.

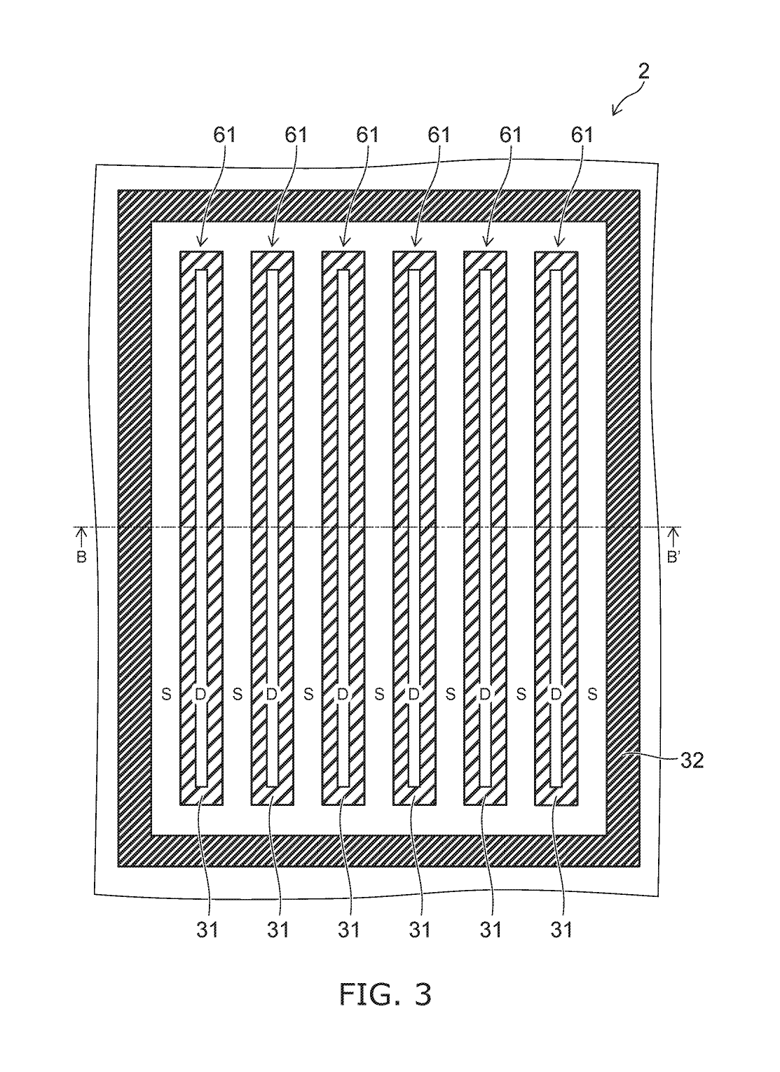

FIG. 3 is a plan view showing a semiconductor device according to the embodiment.

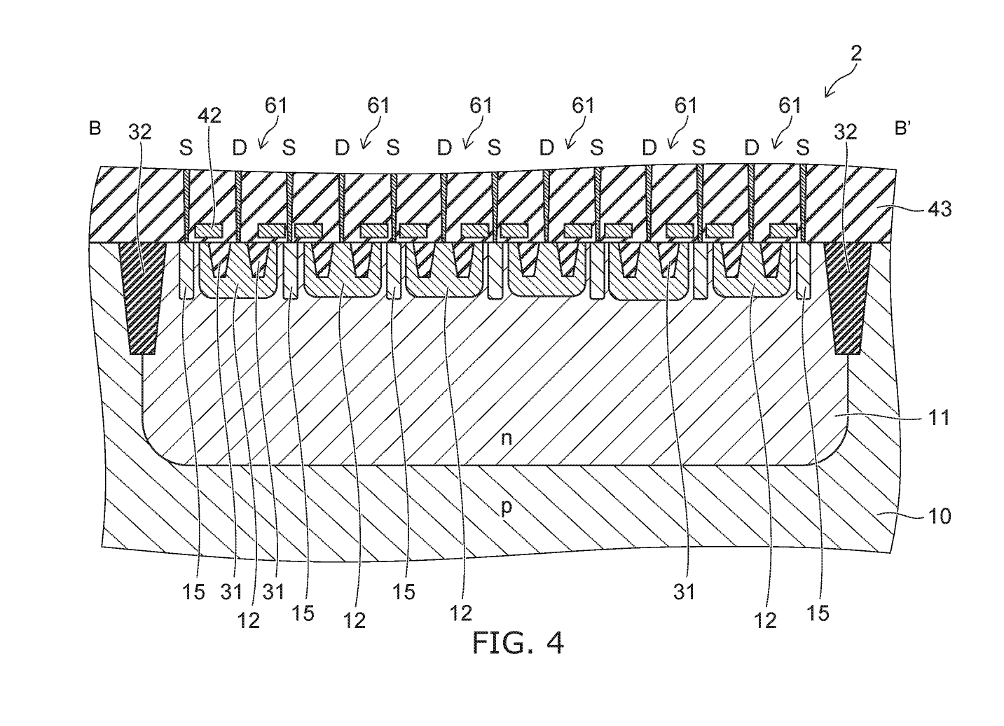

FIG. 4 is a cross-sectional view along line B-B′ shown in FIG. 3.

In FIG. 3 and FIG. 4, only the major components are shown to simplify the drawings.

In the semiconductor device 2 according to the embodiment as shown in FIG. 3 and FIG. 4, multiple DMOSs 61 are provided inside an element region surrounded with the STI 32. The configurations of the DMOSs 61 are as described in the first embodiment described above. In each of the DMOSs 61, the STI 31 is provided between the drain and the channel. The STI 31 is thinner than the STI 32. In other words, in the semiconductor device 2, relatively thin STIs 31 are multiply provided inside an element region surrounded with a relatively thick STI 32.

Otherwise, the configuration, the operations, and the effects of the embodiment are similar to those of the first embodiment described above.

### Third Embodiment

A third embodiment will now be described.

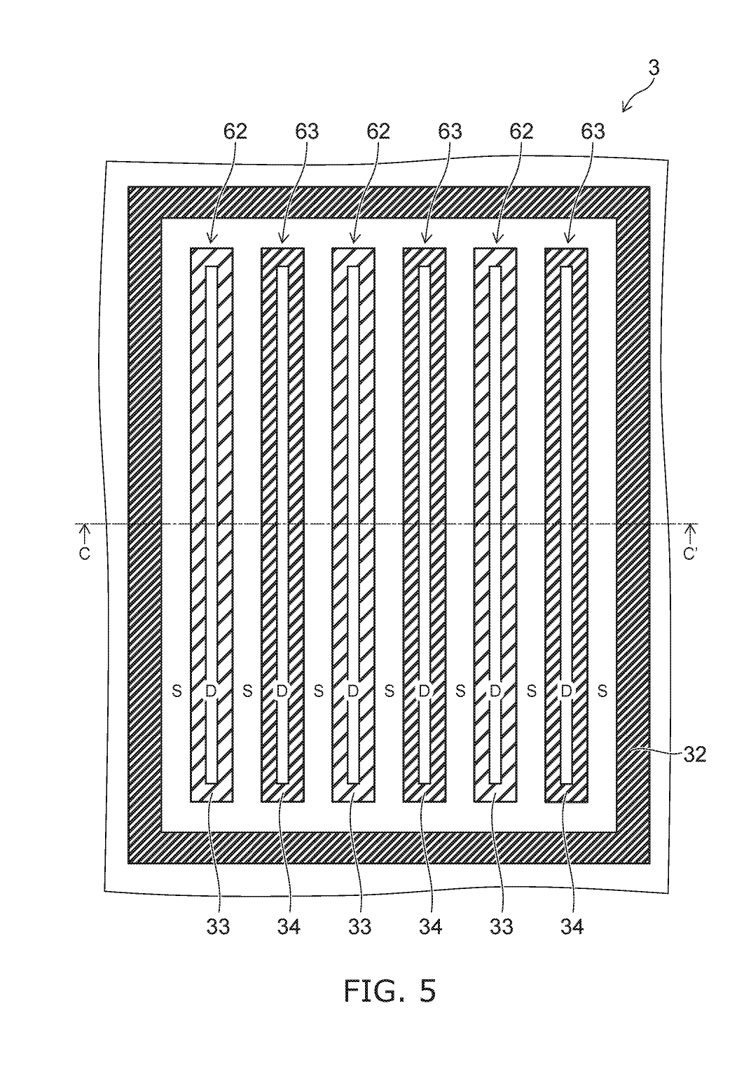

FIG. 5 is a plan view showing a semiconductor device according to the embodiment.

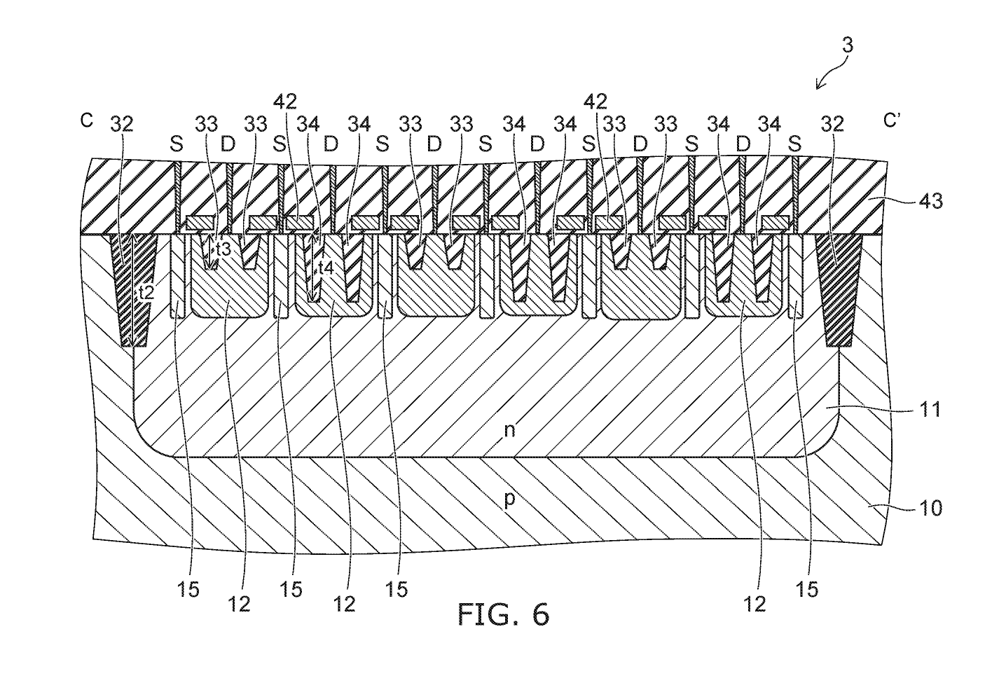

FIG. 6 is a cross-sectional view along line C-C′ shown in FIG. 5.

In FIG. 5 and FIG. 6, only the major components are shown to simplify the drawings.

In the semiconductor device 3 according to the embodiment as shown in FIG. 5 and FIG. 6, multiple DMOSs 62 and multiple DMOSs 63 are formed inside an element region surrounded with the STI 32. The DMOSs 62 and the DMOSs 63 are arranged alternately. In the DMOS 62, a STI 33 is provided between the drain and the channel. In the DMOS 63, a STI 34 is provided between the drain and the channel. Accordingly, the STI 33 and the STI 34 are arranged alternately. The STI 34 is thicker than the STI 33 and thinner than the STI 32. In other words, t3<t4<t2, wherein the thickness of the STI 32 is t2, the thickness of the STI 33 is t3, and the thickness of the STI 34 is t4.

Because the STI 34 is thicker than the STI 33, the breakdown voltage of the DMOS 63 is higher than that of the DMOS 62. Also, the on-resistance is higher and the current flows less easily in the DMOS 63 than in the DMOS 62. Therefore, the heat generation amount of the DMOS 63 is smaller than the heat generation amount of the DMOS 62 when driven under the same conditions.

According to the embodiment, the DMOS 62 and the DMOS 63 that have mutually-different characteristics can be made individually by setting the thicknesses of the STI 33 and the STI 34 to be different. By surrounding the periphery with the deep STI 32, separation from the peripheral region can be provided reliably.

According to the embodiment, by alternately arranging the DMOS 62 having the relatively large heat generation amount and the DMOS 63 having the relatively small heat generation amount, the heat sources can be dispersed; and the temperature of the entirety can be uniform. Therefore, the heat resistance of the semiconductor device 3 is high.

Otherwise, the configuration, the operations, and the effects of the embodiment are similar to those of the first embodiment described above.

### Fourth Embodiment

A fourth embodiment will now be described.

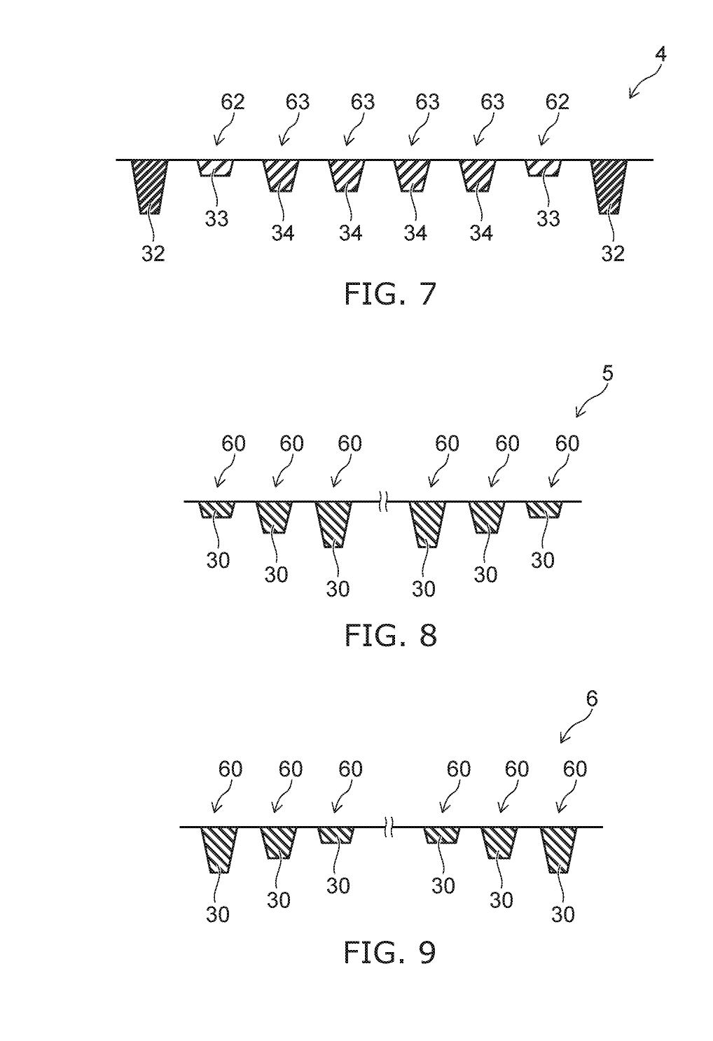

FIG. 7 is a cross-sectional view showing a semiconductor device according to the embodiment.

Only the relationship between the positions and the depths of the STIs are schematically shown in FIG. 7. This is similar for FIG. 8 to FIG. 11 described below as well.

In the semiconductor device 4 according to the embodiment as shown in FIG. 7, the DMOS 63 that has the relatively small heat generation amount is disposed at the central portion inside the element region surrounded with the STI 32; and the DMOS 62 that has the relatively large heat generation amount is disposed at the two end portions of the element region. In other words, the STI 34 is provided at the central portion of the element region; and the STI 33 is provided at the two end portions of the element region.

Generally, in the element region, it is difficult to cool the regions proximal to the central portion; and the temperature increases easily. According to the embodiment, the temperature increase at the central portion can be suppressed by disposing the DMOS 63 having the relatively small heat generation amount at the central portion of the element region. On the other hand, by disposing the DMOS 62 having the relatively large heat generation amount at the two end portions of the element region, heat dissipation can be performed efficiently. As a result, the temperature distribution inside the element region can be uniform; and the heat resistance of the semiconductor device 4 can be improved.

Otherwise, the configuration, the operations, and the effects of the embodiment are similar to those of the first embodiment described above.

### Fifth Embodiment

A fifth embodiment will now be described.

FIG. 8 is a cross-sectional view showing a semiconductor device according to the embodiment.

In the semiconductor device 5 according to the embodiment as shown in FIG. 8, a STI 30 of a DMOS 60 becomes deeper as the DMOS 60 is disposed toward the central portion inside the element region surrounded with the STI 32 (referring to FIG. 7). Thereby, the heat generation amount of the DMOS 60 decreases as the DMOS 60 is disposed toward the central portion of the element region. As a result, the temperature distribution inside the element region can be uniform; and the heat resistance of the semiconductor device 5 can be improved. Although only three levels of the thickness of the STI 30 are shown in FIG. 8, four or more levels may be used.

Otherwise, the configuration, the operations, and the effects of the embodiment are similar to those of the first embodiment described above.

### Sixth Embodiment

A sixth embodiment will now be described.

FIG. 9 is a cross-sectional view showing a semiconductor device according to the embodiment.

In the semiconductor device 6 according to the embodiment as shown in FIG. 9, the STI 30 of the DMOS 60 becomes deeper as the DMOS 60 is disposed toward the terminal portion inside the element region surrounded with the STI 32 (referring to FIG. 7). Although only three levels of the thickness of the STI 30 are shown in FIG. 9, four or more levels may be used.

Otherwise, the configuration, the operations, and the effects of the embodiment are similar to those of the first embodiment described above.

### Seventh Embodiment

A seventh embodiment will now be described.

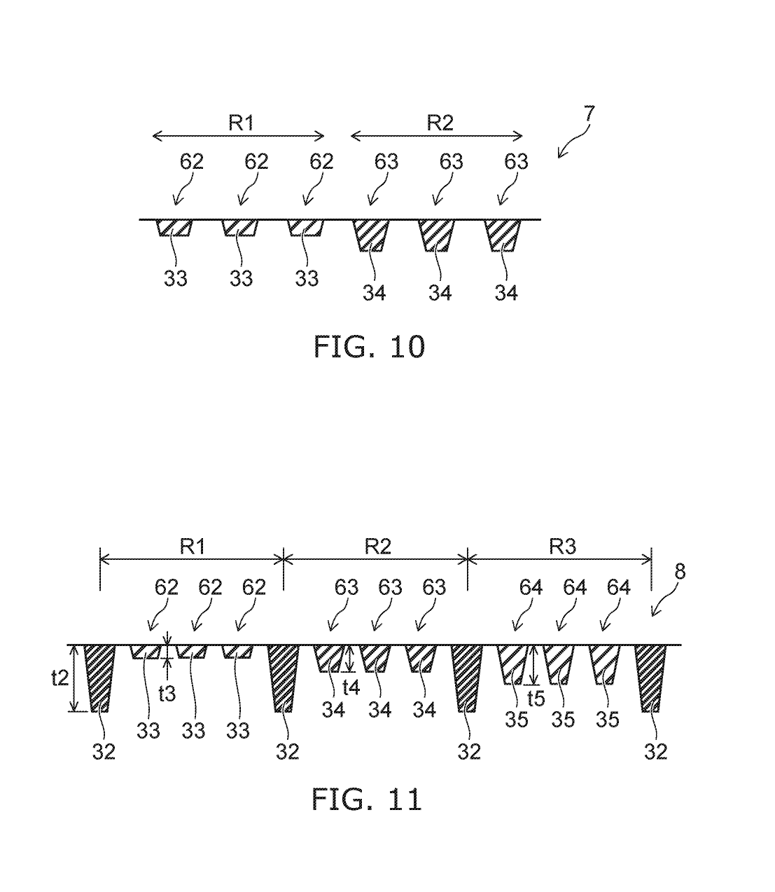

FIG. 10 is a cross-sectional view showing a semiconductor device according to the embodiment.

As shown in FIG. 10, element regions R1 and R2 are set in the semiconductor device 7 according to the embodiment. The multiple DMOSs 62 are provided in the element region R1; and the multiple DMOSs 63 are provided in the element region R2. As described above, the STI 33 is provided in the DMOS 62; and the STI 34 is provided in the DMOS 63. The STI 32 (referring to FIG. 7) may be provided at the periphery of the element region R1 and the periphery of the element region R2.

In the embodiment as well, similarly to the third embodiment described above, DMOSs that have two different types of characteristics can be made individually.

Otherwise, the configuration, the operations, and the effects of the embodiment are similar to those of the first embodiment described above.

### Eighth Embodiment

An eighth embodiment will now be described.

FIG. 11 is a cross-sectional view showing a semiconductor device according to the embodiment.

As shown in FIG. 11, the element regions R1, R2, and R3 are provided in the semiconductor device 8 according to the embodiment. The multiple DMOSs 62 are provided in the element region R1; and the multiple DMOSs 63 are provided in the element region R2. Also, multiple DMOSs 64 are provided in the element region R3. The STI 32 is provided at the periphery of the element region R1, the periphery of the element region R2, and the periphery of the element region R3.

Similarly to the seventh embodiment described above, the STI 33 is provided in the DMOS 62; and the STI 34 is provided in the DMOS 63. A STI 35 is provided in the DMOS 64. The STI 35 is thicker than the STI 34 and thinner than the STI 32. In other words, t3<t4<t5<t2, wherein the thickness of the STI 32 is t2, the thickness of the STI 33 is t3, the thickness of the STI 34 is t4, and the thickness of the STI 35 is t5. As the STI becomes deeper, the breakdown voltage of the DMOS increases; the on-resistance increases; and the heat generation amount decreases.

According to the embodiment, DMOSs that have three different types of characteristics can be mixed.

Otherwise, the configuration, the operations, and the effects of the embodiment are similar to those of the first embodiment described above.

### Ninth Embodiment

A ninth embodiment will now be described.

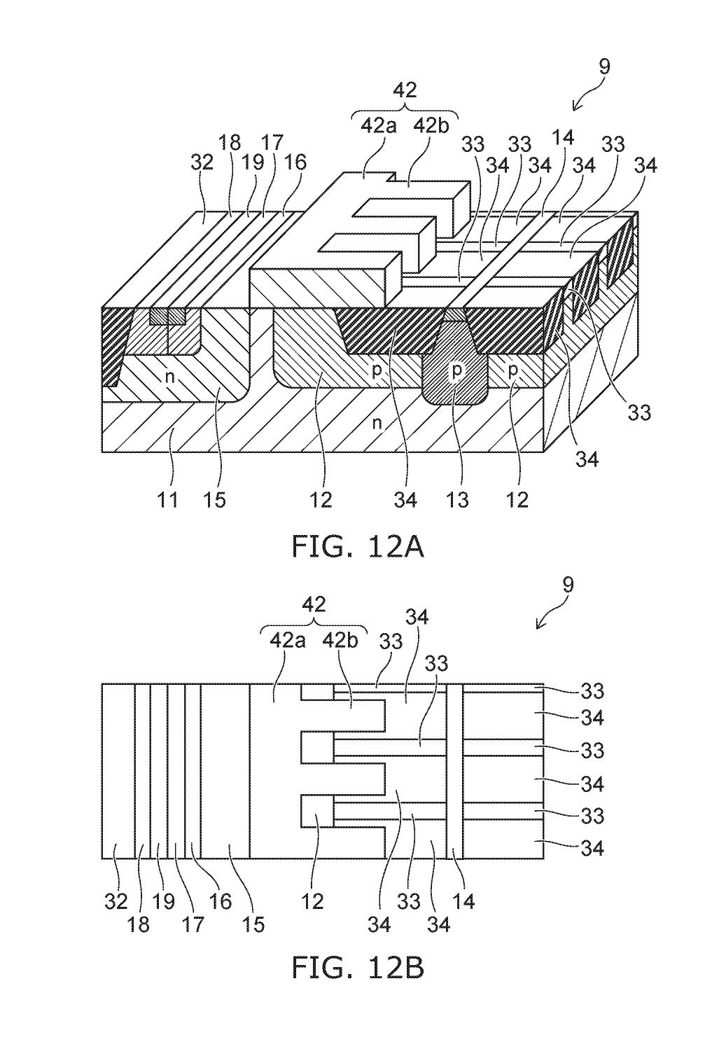

FIG. 12A is a perspective cross-sectional view showing a semiconductor device according to the embodiment; and FIG. 12B is a plan view of the semiconductor device according to the embodiment.

The gate insulating film 41, the inter-layer insulating film 43, the contacts 44 to 47, and the interconnects 48 to 51 are not illustrated in FIGS. 12A and 12B.

As shown in FIGS. 12A and 12B, the configuration of the gate electrode 42 is a comb-shaped configuration in the semiconductor device 9 according to the embodiment. In other words, in the gate electrode 42, one main body portion 42a that extends in a direction (hereinbelow, called the “rearward direction”) in which the source layer 16 extends is provided; and multiple teeth 42b that extend from the main body portion 42a toward the drain contact layer 14 are provided. The teeth 42b are arranged periodically along the rearward direction.

The relatively thick STIs 34 are provided in a region including regions directly under portions of each of the teeth 42b other than the base portion; and the relatively thin STI 33 is provided between the STIs 34. Thereby, the STIs 34 and the STIs 33 are arranged periodically alternately along the rearward direction below the gate electrode 42. The STI 34 and the STI 33 contact each other.

According to the embodiment, a DMOS having excellent balance between the on-resistance and the breakdown voltage can be realized in which the concentration of the electric field is relaxed not only in the two dimensions of the up-down direction and the source-drain direction but also in a three-dimensional space including the rearward direction.

Otherwise, the configuration, the operations, and the effects of the embodiment are similar to those of the first embodiment described above.

### Tenth Embodiment

A tenth embodiment will now be described.

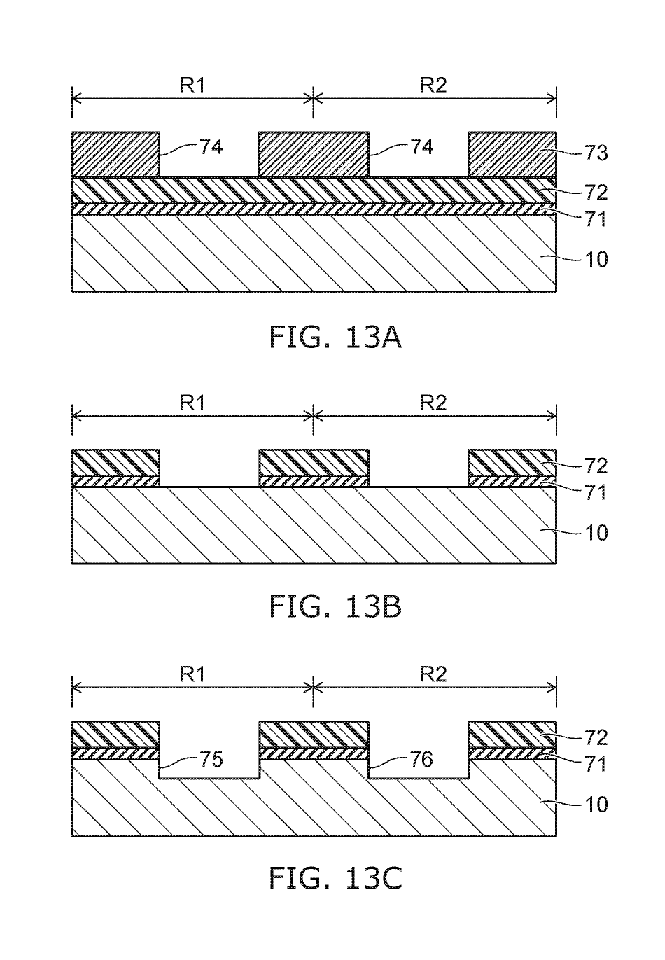

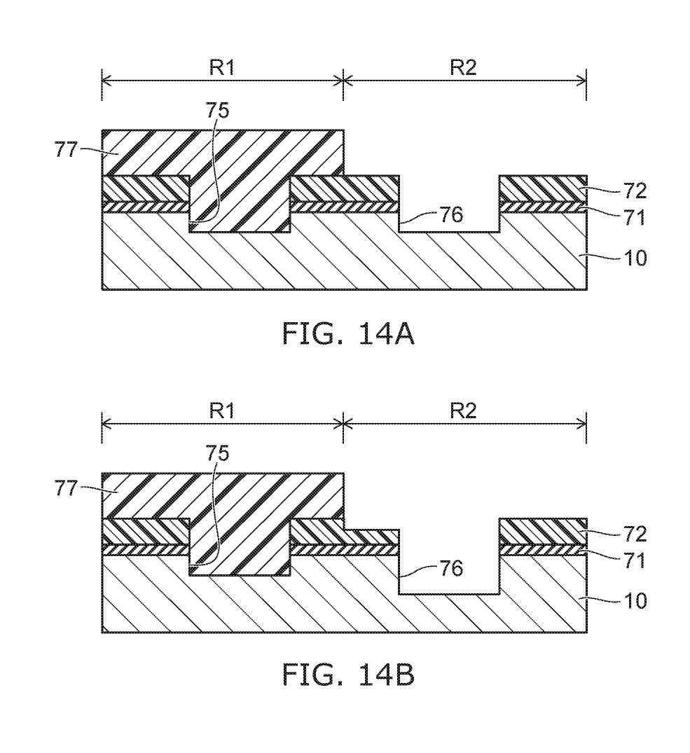

FIGS. 13A to 13C and FIGS. 14A and 14B are cross-sectional views showing a method for manufacturing the semiconductor device according to the embodiment.

In the embodiment, the method for forming the STI in the method for manufacturing the semiconductor device according to the seventh embodiment described above will be described. In FIGS. 13A to 13C and FIGS. 14A and 14B, one STI per element region is shown to simplify the drawings.

First, as shown in FIG. 13A, a silicon oxide film 71 is formed on the silicon substrate 10; and a hard mask film 72 is formed on the silicon oxide film 71. For example, the hard mask film 72 is formed by depositing silicon oxide or by depositing silicon nitride (SiN) by CVD (Chemical Vapor Deposition) using TEOS (Tetraethyl orthosilicate: Si(OC₂H₅)₄) as a source material. Then, a resist film 73 is formed. Openings 74 are formed in the resist film 73 in the element region R1 and the element region R2.

Then, as shown in FIG. 13B, etching such as RIE (Reactive Ion Etching) or the like is performed using the resist film 73 as a mask. Thereby, the hard mask film 72 is patterned; continuing, the silicon oxide film 71 is patterned.

Continuing as shown in FIG. 13C, etching such as RIE or the like is performed using the hard mask film 72 and the silicon oxide film 71 as a mask. Thereby, recesses 75 and 76 are formed in the upper surface of the silicon substrate 10. The recess 75 is formed in the element region R1; and the recess 76 is formed in the element region R2.

Then, as shown in FIG. 14A, a resist film 77 is formed to cover the element region R1 and to expose the element region R2.

Continuing as shown in FIG. 14B, etching such as RIE or the like is performed using the resist film 77, the hard mask film 72, and the silicon oxide film 71 as a mask. Thereby, the bottom surface of the recess 76 is etched to become deeper than the recess 76. At this time, the recess 75 is covered with the resist film 77; therefore, the bottom surface of the recess 75 is not etched; and the depth of the bottom surface of the recess 75 does not change.

Then, the resist film 77 is removed. Continuing, silicon oxide is deposited on the entire surface; and planarization such as CMP (Chemical Mechanical Polishing) or the like of the upper surface is performed. Thereby, the STI 33 (referring to FIG. 10) is filled into the recess 75; the STI 34 (referring to FIG. 10) is filled into the recess 76; and the hard mask film 72 and the silicon oxide film 71 that are on the portion of the silicon substrate 10 other than the recess 75 and the recess 76 are removed. Thus, the STI 33 and the STI 34 that have mutually-different depths are formed in the upper layer portion of the silicon substrate 10. It is also possible to individually make STIs having three or more mutually-different types of depths by repeating the process described above.

According to the embodiments described above, a semiconductor device having excellent balance between the on-resistance and the breakdown voltage can be realized.

Although several embodiments of the invention are described hereinabove, these embodiments are presented as examples and are not intended to limit the scope of the invention. These novel embodiments may be implemented in other various forms; and various omissions, substitutions, and modifications can be performed without departing from the spirit of the invention. Such embodiments and their modifications are within the scope and spirit of the invention and are within the scope of the invention described in the claims and their equivalents. Also, the embodiments described above can be practiced in combination with each other.

Although an example is shown in the embodiments described above in which a DMOS is provided in the semiconductor device, this is not limited thereto. For example, a LDMOS (Laterally Diffused MOS), a DEMOS (Drain Extended MOS), an EDMOS (Extended Drain MOS (orthogonal gate extended drain MOS)), or a high breakdown voltage MOSFET (Metal-Oxide-Semiconductor Field-Effect Transistor) may be provided.

Although an example is shown in the embodiments described above in which a silicon substrate is used as the semiconductor substrate, this is not limited thereto. The semiconductor substrate may be, for example, a SiC substrate, a SiGe substrate, or a compound semiconductor substrate.

What is claimed is:

1. A semiconductor device, comprising:
a semiconductor substrate;
a plurality of first insulators provided in an upper portion of the semiconductor substrate; and
a plurality of second insulators provided in the upper portion of the semiconductor substrate, the plurality of second insulators being thicker than the plurality of first insulators,
the first insulators and the second insulators being arranged alternately.

2. The device according to claim 1, further comprising:
a first source layer provided on the semiconductor substrate, the first source layer being of a first conductivity type;
a first drain layer provided on the semiconductor substrate, the first drain layer being of the first conductivity type,
a second source layer provided on the semiconductor substrate, the second source layer being of the first conductivity type; and
a second drain layer provided on the semiconductor substrate, the second drain layer being of the first conductivity type,
at least an upper layer portion of the semiconductor substrate being of a second conductivity type,
the first insulator being disposed between the first drain layer and a first channel region of the semiconductor substrate, the first channel region being disposed between the first source layer and the first drain layer, and
the second insulator being disposed between the second drain layer and a second channel region of the semiconductor substrate, the second channel region being disposed between the second source layer and the second drain layer.

3. The device according to claim 1, wherein a distance between an upper surface of one of the first insulators and an upper surface of one of the second insulators is shorter than a distance between a lower surface of the one of the first insulators and a lower surface of the one of the second insulators in a vertical direction.

4. The device according to claim 1, further comprising an element-separating insulator surrounding the first insulators and the second insulators, the element-separating insulator being thicker than the second insulators.

5. A semiconductor device, comprising:
a semiconductor substrate;
a first source layer provided on the semiconductor substrate;
a first drain layer provided on the semiconductor substrate;
a first insulator disposed between the first drain layer and a first channel region of the semiconductor substrate, the first channel region being disposed between the first source layer and the first drain layer;
a second source layer provided on the semiconductor substrate;
a second drain layer provided on the semiconductor substrate;
a second insulator disposed between the second drain layer and a second channel region of the semiconductor substrate, the second channel region being disposed between the second source layer and the second drain layer;
a third source layer provided on the semiconductor substrate;
a third drain layer provided on the semiconductor substrate; and
a third insulator disposed between the third drain layer and a third channel region of the semiconductor substrate, the third channel region being disposed between the third source layer and the third drain layer,
the second insulator being disposed between the first insulator and the third insulator,
the second insulator being thicker than the first insulator and the third insulator.

6. The device according to claim 5, wherein a distance between an upper surface of the first insulator and an upper surface of the second insulator is shorter than a distance between a lower surface of the first insulator and a lower surface of the second insulator in a vertical direction.

7. The device according to claim 5, further comprising an element-separating insulator surrounding the first insulator, the second insulator and the third insulator, the element-separating insulator being thicker than the second insulator.

8. A semiconductor device, comprising:
a semiconductor substrate;
a plurality of first insulators provided in an upper portion of the semiconductor substrate in a first element region;
a plurality of second insulators provided in the upper portion of the semiconductor substrate in a second element region, the plurality of second insulators being thicker than the plurality of first insulators; and
an element-separating insulator provided between the first element region and the second element region, the element-separating insulator being thicker than the second insulators.

9. The device according to claim 8, further comprising:
a source layer provided on the semiconductor substrate, the source layer being of a first conductivity type; and
a drain layer provided on the semiconductor substrate, the drain layer being of the first conductivity type,
at least an upper layer portion of the semiconductor substrate being of a second conductivity type,
the first insulator being disposed between the drain layer and a channel region of the semiconductor substrate, the channel region being disposed between the source layer and the drain layer.

10. The device according to claim 8, wherein a distance between an upper surface of one of the first insulators and an upper surface of one of the second insulators is shorter than a distance between a lower surface of the one of the first insulator and a lower surface of the one of the second insulator in a vertical direction.
